(19) United States
(12) Patent Application Publication
(10) Pub. No.: US 2007/0259537 A1
(43) Pub. Date: Nov. 8, 2007

(54) COATED MICROWAVE PLUG CONNECTOR AND COOKING APPLIANCE WITH SUCH A MICROWAVE PLUG CONNECTOR

(75) Inventor: Peter Kohlstrung, Kaufering (DE)

Correspondence Address: MARSHALL, GERSTEIN & BORUN LLP, 233 S. WACKER DRIVE, SUITE 6300, SEARS TOWER, CHICAGO, IL, 60606, US

(73) Assignee: TOPINOX SARL, Wittenheim (FR)

(21) Appl. No.: 11/743,551

(22) Filed: May 2, 2007

(30) Foreign Application Priority Data
May 3, 2006 (EP) 06290732.4

(51) Int. Cl. H05K 1/00

(52) U.S. Cl. 439/63

(57) ABSTRACT

A cooling appliance with a microwave plug connector or such a microwave plug connector, comprises an emitter unit an a receiver unit, whereby the emitter unit is connected to a microwave source for feeding microwaves having wavelength λ, the receiver unit is connected to the emitter unit for transmission of microwaves, a dielectric is arranged between the emitter unit and the receiver unit at least in some areas, the emitter unit has at least one metallic conductor in connection with a metallic λ/4 structure, the receiver unit comprises at least one metallic conductor in connection with a metallic λ/4 structure, the two λ/4 structures can be connected on top of one another or to one another, especially separably, and the dielectric is provided as a dielectric coating of at least a part of at least one of the λ/4 structures, which functions as a metallic substrate in the region of connecting on top of one another or together of the λ/4 structure.

### BACKGROUND

1. Field of the Invention

The invention concerns a microwave plug connector comprising an emitter unit and a receiver unit, whereby the emitter unit is connected to a microwave source for the feeding of microwaves having wavelength λ, the receiving unit being connected to the emitter unit for the transmission of microwaves, and a dielectric is arranged between the emitter unit and the receiver unit at least in some areas, and a cooking appliance with a cooking chamber, a technical chamber separated from the cooking chamber with at least one cooking chamber wall and a microwave plug connector according to the invention.

2. Related Technology

A cooking appliance with a microwave generator device is described, for example, in the not pre-published EP 05026912.5. According to that, a coaxial or strip conductor can be integrated in an accessory within a cooking chamber for the transmission of microwaves and can be provided with a contact and/or coupling device in order to be able to be connected to a microwave generator device arranged outside the cooking chamber. The contact and/or coupling device can be screened electrically or magnetically, can be sealed against steam and/or be stable to a temperature of at least up to 250° C. and comprise a plug connector. However, further details of this plug connector are not described.

U.S. Pat. No. 5,977,841 discloses a generic, contact-free microwave plug connector for transmitting high-frequency energy through a ship's hull with a dielectric layer inserted in-between. Hereby two coaxial plug parts are used in which a dielectric material is arranged both between the particular inner and outer conductors as well as between the two plug parts. The dielectric material has the purpose of preventing corrosion of the metal of the plug-in parts by salt water or preventing the growth of marine organisms. The impedance of the known microwave plug connector is adjusted by the thickness of the dielectric layer(s) in such a way that a transmission of microwaves at a wavelength of all can occur with as little loss as possible. Teflon is named as a preferred material for each dielectric layer. In addition, it is known from U.S. Pat. No. 5,977,841 that λ/4 effects can be utilized for avoiding reflectioins, for example by arranging a parallel capacitor at a distance of λ/4 from the dielectric between the two plug parts in the particular coaxial line.

The disadvantage of these known microwave plug connectors is that they are not suited to withstand either the temperatures or temperature changes in a cooking chamber or the mechanical loads to which such a connector is exposed in daily use in a large and industrial kitchen. The high temperatures in the cooking chamber, which may exceed 300° C. for a brief period of time, destroy organic dielectrics, such as, for example, Teflon. The high thermal stress, which can arise, for example, as a result of a cold liquid impinging on the hot microwave plug connector or simply when the cooking chamber is just heated with high energy input, can cause a mechanical strain because of the different thermal expansions of metal and dielectric and finally can cause destruction of the microwave plug connector. Another problem, which arises from the high and rapidly changing temperatures in the cooking chamber, is the change of the geometrical relationships in the microwave plug connector as a result of thermal expansion. The deviations from an optimum λ/4 geometry resulting from this will result in an increase of the impedance and thus in losses during energy transmission through the microwave plug connector.

### GENERAL DESCRIPTION

Therefore, the task of the invention is to further develop the generic microwave plug connector so that the disadvantages of the prior art are overcome. Especially, a thermally and mechanically stable microwave plug connector is provided which can be used in a cooking appliance in daily cooking operations. In addition, the microwave plug connector is designed to be as simple and cost-effective as possible and to minimize failures during simple operation. Also, the transmission of microwave energy through the connector keeps losses as low as possible.

According to one aspect of the invention, this task is solved by the fact that the emitter Unit comprises at least one metallic conductor in combination with a metallic λ/4 structure, the receiver unit comprises at least one metallic conductor in connection with a metallic λ/4 structure, the two λ/4 structures being especially connectable on top of one another or to one another, and the dielectric provided as a dielectric coating at least on one part of at least one of the λ/4 structures, which functions as a metallic substrate, in the region where the λ/4 structures are stacked on top of one another or attached together.

Hereby, it can be provided that the dielectric coating is connected elastically to the metallic substrate.

Furthermore, it can be provided that the dielectric coating is porous.

According to the invention, it is also proposed that the dielectric coating be sealed with a mineral melt at least in some areas for stabilization.

Furthermore, it can be provided that the dielectric coating consists of a ceramic material.

It is also proposed according to the invention, that the dielectric coating comprises aluminum oxide.

Furthermore, it can be provided that the dielectric coating fills the intermediate space between the λ/4 structures.

According to the invention, it is further proposed that the dielectric coating serves to influence the electric field between the λ/4 structures.

In preferred practical examples of the invention, the emitter unit comprises a coaxial line with an inner conductor and an outer conductor, whereby the inner conductor and the outer conductor are each designed as metallic conductors in connection with a λ/4 structure, the receiver unit has a coaxial line with an inner conductor and an outer conductor, whereby the inner conductor and the outer conductor are each designed as metallic conductors in connection with a λ/4 structure, the λ/4 structures of the inner conductors and/or the λ/4 structures of the outer conductors can be plugged in on top of one another or together, and at least one of the λ/4 structures of the inner conductors is provided with a dielectric coating at least in some areas, whereby preferably the λ/4 structure of the inner conductor of the emitter unit is provided with a dielectric coating at least in some areas.

Hereby, it can be provided that the outer conductor of the emitter unit and the receiver unit are connected together galvanically, or the λ/4 structure of the outer conductor of the emitter unit is provided with a dielectric coating at least in some areas.

It is also proposed with the invention that each inner conductor and/or each outer conductor and/or each λ/4 structure comprises stainless steel and/or copper and/or brass.

Furthermore, it can be proposed that at least one dielectric insulation in the emitter unit and/or in the receiver unit separates the particular inner conductor from the particular outer conductor galvanically, at least in some areas of the particular λ/4 structures.

Hereby, it is proposed that the dielectric insulation seals the coaxial line of the emitter unit in a water-tight manner at least on the end that faces away from the microwave source, preferably by inserting at least one O-ring seal.

Embodiments of the invention can be characterized by the fact that one of the inner conductors is in working connection with a nose, especially a pin-like nose, while the other inner conductor that can be connected to a recess that is adapted to the nose, whereby preferably both the nose as well as the recess has a λ/4 structure.

Hereby, it can be provided that the nose is a component of a contacting means that is connected to the corresponding inner conductor by positive locking and/or non-positive locking.

Hereby, it is proposed with the invention that the dielectric insulation is positioned between the contacting means and the outer conductor belonging to the inner conductor that is connected to it, preferably through the intermediate connection of at least one O-ring seal.

According to the invention it can also be provided that the λ/4 structures of the outer conductors of the emitter unit and the receiver unit can be plugged in on top of one another, especially in a manner so that they lie flat on one another.

The invention also provides a cooking appliance with a cooking chamber, and with a technical chamber which is separated from the cooking chamber by at least one cooking chamber wall, and with a microwave plug connector according to the invention described herein, in which the emitter unit is arranged in the technical chamber and the receiver unit IS arranged in the cooking chamber.

Hereby, it can be provided that the emitter unit is connected to the cooking chamber wall mechanically, especially separably.

Hereby, it is again proposed by the invention that the λ/4 structure of the outer conductor of the emitter unit has a thread.

Finally, it can also be provided with the invention that the receiver unit is surrounded by an accessory of the cooking appliance, preferably a post for a cooking product rack.

Thus, the invention is based on the surprising finding that a microwave plug connector is stable thermally and mechanically to such an extent that it can be used even in a cooking appliance for large and industrial kitchens, in that a dielectric is provided as a coating that is solidly affixed to a metallic substrate that is attached to a (coaxial) line, has a λ/4 structure and serves to provide galvanic separation at least in some areas where the (coaxial) line connects with another (coaxial) line for transferring microwaves with a wavelength of λ. Also, the other line can also be equipped with such a dielectric coating.

The connection according to the invention becomes especially thermally stable by the fact that the coating is applied on the substrate in an elastic and porous manner. Moreover, the mechanical stability of the connection can be increased due to the fact that the dielectric coating consists of a ceramic material, preferably aluminum oxide, and advantageously it is also sealed with a mineral melt.

When using a microwave plug connector according to the invention in a cooking appliance with a cooking chamber and a technical chamber, also called equipment chamber, a receiver unit on the cooking chamber side and/or an emitter unit on the technical chamber side is provided with a dielectric coating. In addition, on the technical chamber side another dielectric can be arranged for fluid sealing, namely between the inner conductor and outer conductor of the emitter unit, which separates the inner conductor and the outer conductor of the emitter unit galvanically from one another.

According to the invention, the receiver unit and emitter unit are designed as parts of a tightly holding separable plug. With the aid of a thread in the area of the λ/4 structure of the outer conductor of the emitter unit, it can be screwed in tightly to a cooking chamber wall. Hereby, care must be taken that the thickness of the dielectric coating is adapted to the λ/4 geometry of the connector.

Further characteristics and advantages of the invention follow as examples from the detailed description given below of a preferred embodiment of the invention with the aid of schematic drawings. The following are shown hereby:

### BRIEF DESCRIPTIONS OF THE DRAWINGS

FIG. 1 is a longitudinal section of an emitter unit and a receiver unit of a microwave plug connector according to the invention in a non-plugged in condition; and

FIG. 2 is a longitudinal section of the microwave plug connector of FIG. 1 in a plugged-in condition.

### DETAILED DESCRIPTION

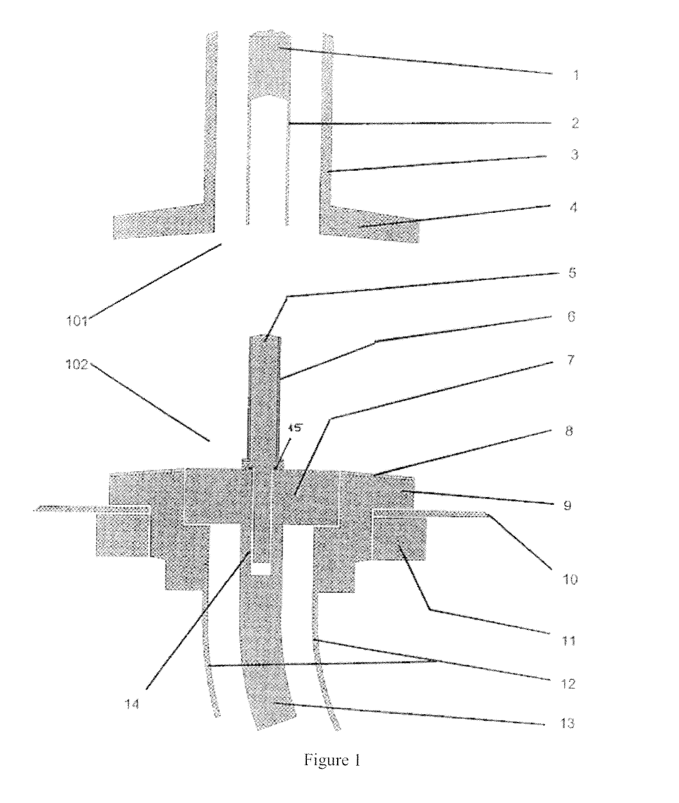

FIG. 1 shows a microwave plug connector 100 according to the invention to be used in a cooking appliance (not shown) with cooking chamber walls 10 between a cooking chamber and a technical chamber, namely with a connector on the cooking chamber side in the form of a receiver unit 101 and a connector on the technical chamber side in the form of an emitter unit 102.

In the emitter unit 102, through a feeding coaxial microwave line with outer conductor 12 and inner conductor 13, microwaves with a wavelength λ are introduced from a microwave source (not shown) to the microwave plug connector 100. Through a contacting means 14, the microwaves are introduced from the feeding inner conductor 13 to an emitter inner conductor 5 with λ/4 structure, while the outer conductor 12 extends into an emitter outer conductor with λ/4 structure. The λ/4 structures of the emitter conductors 5, 9 are seperated from one another galvanically and spatially by a water-tight dielectric 7, namely with an O-ring seal 15 inserted in-between. This emitter unit 102 is connected to the cooking chamber walls 10 with the aid of an attaching element 11. The λ/4 structure of the emitter outer conductor 9 has a dielectric coating 8 on the cooking chamber side. Similarly, the λ/4 structure of the emitter inner conductor 5 has a dielectric coating 6.

The receiver unit 101 can be plugged on top of the emitter unit 102, the receiver unit having a continuing microwave inner conductor 1 and a continuing microwave outer conductor 3, each of which are connected to a receiving a λ/4 structure 3 and 4, respectively.

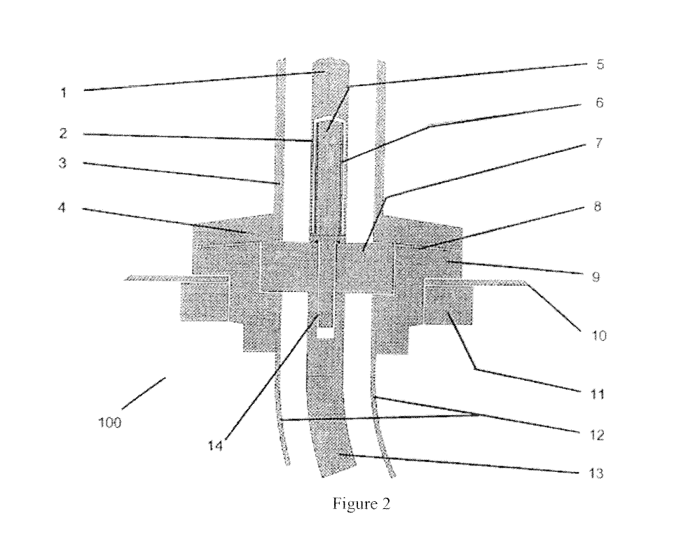

FIG. 2 shows the microwave plug connector 100 in the plugged-in state, whereby the receiver unit 101 can be connected to the emitter unit 102 solidly both with positive or non-positive locking, for example, with the aid of a nut. The geometry of the λ/4 structures 2, 4, 5, 9 of the dielectric coatings 6, 8 and of the dielectric insulator 7 are designed so that the microwaves entering into the emitter unit 102 can be transmitted to the receiver unit 101 with as little loss as possible. This is provided by adjusting the geometry of the components to the wavelength λ, of the microwave.

The electrical and magnetic fields of the microwaves penetrate into the non-conducting dielectric layers or coatings 6, 8 and thus transfer their energy from the λ/4 structures 5, 9 of the emitter unit 1120 to the λ/4 structures 2, 4 of the receiver unit 101. From there, the microwave energy is introduced through the conducting coaxial microwave line 1, 3 further into the cooking chamber. Ideally, the coaxial receiver line 12 in the cooking chamber also serves as supporting structure of a cooking product carrier construction (not shown), as described in the not pre-published EP 05026912.5. Then the microwave energy, as proposed in the not pre-published DE 10 2006 007 734.2, can be introduced to the cooking product in the cooking chamber with the aid of a suitable antenna structure.

The coatings 6, 8 of the λ/4 structures 5, 9 of the emitter unit 102 can be produced by gas-phase deposition (CVD) or by means of deposition of a plasma in the form of a porous ceramic for example, made of aluminum oxide. Such a coating technique has been described, for example, in US 2005/0260411 A1. The dielectric coatings 6, 8 thus applied are notable for their high mechanical hardness and for a high chemical stability, which is far superior to the metallic parts of the microwave plug connector 100 made, for example, of copper, iron, brass, or stainless steel. By applying the porous ceramic layer with CVD or plasma techniques, a mechanically extremely stable connection of the dielectric ceramic to the metallic substrate is achieved, which also has elastic properties. Such an elastic connection withstands even the mechanical loads during everyday large kitchen operations. Thus, the microwave plug connector according to the invention can be plugged in and pulled apart again often without special precautions. In addition, by the ceramic coating, operation of the cooking appliance is possible even with chemically aggressive substances at high temperatures without the chemical decomposition of the metal of the microwave plug connector. By means of the porous elastic connection to the metallic substrate, furthermore, at high heat fluxes through the microwave plug connector according to the invention, as cannot be avoided during the use in cooking appliances, and in which the substrate and the coating are heated and cooled at different rates, a part of the mechanical forces caused by the different thermal expansion coefficients of the two materials, is absorbed. Thus, the coatings will not peel off from the metallic substrate even upon application of high thermal stress.

In another embodiment according to the invention, the coatings can be coated over with mineral melt, which fills in the pores of the porous ceramic, thus providing additional stabilization of the dielectric layer without thereby disturbing the dielectric properties.

In another possible embodiment of the invention, both the λ/4 structures 5, 9 of the emitter unit 102 as well as the λ/4 structure 2, 4 of the receiver unit 101 are provided with a dieletric coating. Alternatively, only the λ/4 structures of the receiver unit 101 may be coated. In each case, care must be taken that no great deviations from the optimum λ/4 structure geometry of the microwave plug connector 100 according to the invention occur as a result of the coatings.

The characteristics of the invention disclosed in the above specification, in the claims as well as in the drawings, include aspects of the invention both individually as well as in arbitrary combination for the realization of the invention in its various embodiments.

1-21. (canceled)

22. Cooking appliance with a cooking chamber, a technical chamber separated from the cooking chamber by at least one cooking chamber wall and a microwave plug connector, comprising an emitter unit and a receiver unit, whereby
the emitter unit is connected to a microwave source for feeding in microwaves with a wavelength λ, and is arranged in the technical chamber, as the emitter unit comprises a metallic conductor in connection with a metallic λ/4 structure,
the receiver unit is connected to the emitter unit for the transmission of microwaves, and is arranged in the cooking chamber, the receiver unit comprises at least one metallic conductor in connection with a metallic λ/4 structure, the two λ/4 structures can be connected at least one of on top of one another and together, separably, and a dielectric is arranged in at least one region between the emitter unit and the receiver unit,
the dielectric is provided as a dielectric coating of at least one part of at least one of the λ/4 structures, which serves as a metallic substrate, in a region where there is a connection of the λ/4 structures by plugging them at least one of on top of one another and together.

23. Cooking appliance according to claim 22, wherein the dielectric coating is connected elastically to the metallic substrate.

24. Cooking appliance according to claim 22, wherein the dielectric coating is porous.

25. Cooking appliance according to claim 22, wherein the dielectric coating is sealed with a mineral melt for stabilization, at least in some areas.

26. Cooking appliance according to claim 22, wherein the dielectric coating consists of a ceramic material.

27. Cooking appliance according to claim 22, wherein the dielectric coating comprises aluminum oxide.

28. Cooking appliance according to claim 22, wherein the dielectric coating substantially completely fills the intermediate space between the λ/4 structures.

29. Cooking appliance according to claim 22, wherein the dielectric coating serves to influence the electric field between the λ/4 structures.

30. Cooking appliance according to claim 22, wherein the emitter unit comprises a coaxial line with an inner conductor and an outer conductor, whereby the inner conductor and the outer conductor each are designed as metallic conductors in connection with a λ/4 structure, the receiver unit comprises a coaxial line with an inner conductor and an outer conductor, whereby the inner conductor and the Outer conductor each are designed as metallic conductors in connection with a λ/4 structure, at least one of the λ/4 structures of the inner conductors and the λ/4 structures of the outer conductor can be connected one of on top of one another and together, and
at least one of the λ/4 structures of the inner conductors is provided with a dielectric coating at least in some areas.

31. Cooking appliance according to claim 30, wherein one of the outer conductors of the emitter unit and of the receiver unit are connected to one another galvanically, and the λ/4 structure of the outer conductor of the emitter unit is provided with a dielectric coating at least in some areas.

32. Cooking appliance according to claim 30, wherein at least one of each inner conductors, each outer conductor, and each λ/4 structure comprises at least one of stainless steel, copper, and brass.

33. Cooking appliance according to claim 30, wherein at least one dielectric insulation in at least one of the emitter unit and in the receiver unit separates the particular inner conductor galvanically from the particular outer conductor at least in the area of the particular λ/4 structures.

34. Cooking appliance according to claim 33, wherein the dielectric insulation seals the coaxial line of the emitter unit in a water-tight manner at least at the end facing away from the microwave source.

35. Cooking appliance according to claim 30, wherein one of the inner conductors is in working connection with a nose, especially a pin-like nose, while the other inner conductor that can be connected to it has a recess adapted to the said nose.

36. Cooking appliance according to claim 35, wherein the nose is a component of a contacting means, which is connected to the corresponding inner conductor by positive or non-positive locking.

37. Cooking appliance according to claim 36, wherein the fact that the dielectric insulation is arranged between the contacting means and the outer conductor belonging to the inner conductor connected to it.

38. Cooking appliance according to claim 30, wherein the λ/4 structures of the outer conductor of the emitter unit and of the receiver unit can be plugged in on top of one another, especially can be placed on one another in a flat manner.

39. Cooking appliance according to claim 22, wherein the emitter unit is connected to the cooking chamber wall mechanically.

40. Cooking appliance according to claim 39, wherein λ/4 structure of the outer conductor of the emitter unit has a thread.

41. Cooking appliance according to claim 22, wherein the receiver unit is surrounded by an accessory of the cooking appliance.

42. Cooking appliance according to claim 30, wherein the λ/4 structure of the inner conductor of the emitter unit is provided with a dielectric coating at least in some areas.

43. Cooking appliance according to claim 34, wherein the dielectric insulation provides the seal by the insertion of at least one O-ring seal.

44. Cooking appliance according to claim 35, wherein the nose is λ/4 structure and the recess is a λ/4 structure.

45. Cooking appliance according to claim 37, wherein the dielectric insulation is arranged with the insertion of at least one O-ring seal.

46. Cooking appliance according to claim 41, wherein the accessory comprises a post for a cooking product rack.

47. Cooking appliance according to claim 39 wherein the emitter unit is separably connected to the cooking chamber wall.
